(19) United States
(12) Patent Application Publication
(10) Pub. No.: US 2007/0040932 A1
(43) Pub. Date: Feb. 22, 2007

(54) Image sensor module

(76) Inventor: Wen-Ching Chen, Dali City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/206,845

(22) Filed: Aug. 19, 2005

(51) Int. Cl. H04N 5/225

(52) U.S. Cl. 348/374

(57) ABSTRACT

An image pickup module with an image sensor packaged by way of flip chip, including: a base seat formed with a cavity and having a lead frame embedded in the base seat, the lead frame having multiple outer leads for connecting with a circuit board and multiple inner leads extending from the outer leads into the cavity of the base seat; an image sensor inlaid in the cavity of the base seat, the image sensor being composed of a glass substrate and an image sensing chip bonded with a surface of the glass substrate by way of flip chip, multiple circuits being laid on the surface of the glass substrate for electrically connecting with the image sensing chip and the inner leads; and a soft pad abutting against lower sides of the inner leads.

### BACKGROUND OF THE INVENTION

The present invention is related to an image pickup module composed of an image sensor and a lens unit packaged by way of flip chip.

A conventional image sensor includes an image sensing chip disposed on a chip seat. The leads of the chip seat are connected with the image sensing chip via wires. The chip seat is packaged with a transparent cover boar to form the image sensor. After the image sensor is mounted on a circuit board, a lens seat is further installed on the image sensor. A lens barrel is screwed in the lens seat and lenses are arranged in the lens barrel.

After the image sensor is packaged, the image sensor must first go through various tests and then be supplied to a succeeding user. The succeeding user solders the image sensor and other electronic elements on the circuit board and then install a lens holder to enclose the image sensor. Thereafter, the completely assembled circuit board is tested to check its functions, especially the image pickup quality.

When tested, the circuit board is often found to have defects in image pickup quality. The reasons are concluded as follows:
(a) The surface of the glass board of the image sensor is damaged or stained with dusts. This will affect the quality of the image formed on the image sensing chip.
(b) The optical axis of the lens is not aligned with the center. This leads to chromalism on the edges of the picked up image.
(c) The focusing plane of the lens fails to precisely fall onto the surface of the sensing region of the image sensing chip. This results in fogged image. This problem generally can be solved by means of adjusting the lens barrel. However, sometimes the problem just cannot be solved even when the lens barrel is turned to the bottommost position. This may be caused by the manufacturing error of the lenses or the entire lens unit or the deviation of the image sensing chip attaching to the chip seat.

No matter how, the above factors will all lead to defects of the product and affect the production efficiency. Most of the problems can be solved or improved. However, in the case that the image sensor itself has problem in sensing quality or there is error in precision of packaging, the problems will be hard to solve. On the other hand, currently, it is a trend to package the image sensor by way of flip chip. According to such manufacturing procedure, the chip is soldered with the circuit contacts on the glass substrate to achieve optimal electric characteristics, better heat radiation of crystalline grains and smaller package size. However, the leads reserved for such package are very fine and are arranged very densely. With respect to a succeeding user, a very sophisticated surface adhesion equipment is required for adhering the CSP image sensor to the circuit board. Therefore, the flip chip technique is not widely applied to the packaging of the image sensor.

### SUMMARY OF THE INVENTION

It is therefore a primary object of the present invention to provide an image sensor module including a base seat, an image sensor inlaid in the base seat and a lens unit mounted on the base seat in alignment with the image sensor. The module can be previously tested in function. Moreover, various surface adhesion equipments with different precision grades can be applied to the image sensor module.

According to the above object, the image pickup module with an image sensor packaged by way of flip chip of the present invention includes:

a base seat formed with an assembly space, the assembly space having an opening formed on a bottom face of the base seat, a lead frame being embedded in the base seat, the lead frame having multiple outer leads for connecting with a circuit board, the lead frame further having multiple inner leads extending from the outer leads into the assembly space;

an image sensor inlaid in the assembly space of the base seat, the image sensor being composed of a glass substrate and an image sensing chip bonded with a surface of the glass substrate by way of flip chip, multiple circuits being laid on the surface of the glass substrate for electrically connecting with the image sensing chip and the inner leads;

a soft pad disposed at the opening of the assembly space, the soft pad having a first surface abutting against the inner leads and an opposite second surface for attaching to the circuit board; and

an image forming unit assembled with the base seat for forming image on the image sensing chip.

The present invention can be best understood through the following description and accompanying drawings wherein:

### BRIEF DESCRIPTION OF THE DRAWINGS

FIG. 1 is a sectional exploded view of a first embodiment of the image pickup module of the present invention;

FIG. 2 is a sectional assembled view of the first embodiment of the image pickup module of the present invention;

FIG. 3 is a top view showing the base seat and the lead frame of the first embodiment of the image pickup module of the present invention;

FIG. 4 is a sectional assembled view of a second embodiment of the image pickup module of the present invention;

FIG. 5 is a top view showing the base seat and the lead frame of the second embodiment of the image pickup module of the present invention;

FIG. 6 is an enlarged sectional view showing a part of the glass substrate of the image pickup module of the present invention;

FIG. 7 is an enlarged sectional view showing a part of the inner lead and soft pad of the image pickup module of the present invention;

FIG. 8 is a top view of another type of base seat of the image pickup module of the present invention;

FIG. 9 is a sectional assembled view of a third embodiment of the image pickup module of the present invention; and

FIG. 10 is a sectional assembled view of a module composed of a lens unit and an image sensor.

### DETAILED DESCRIPTION OF THE PREFERRED EMBODIMENTS

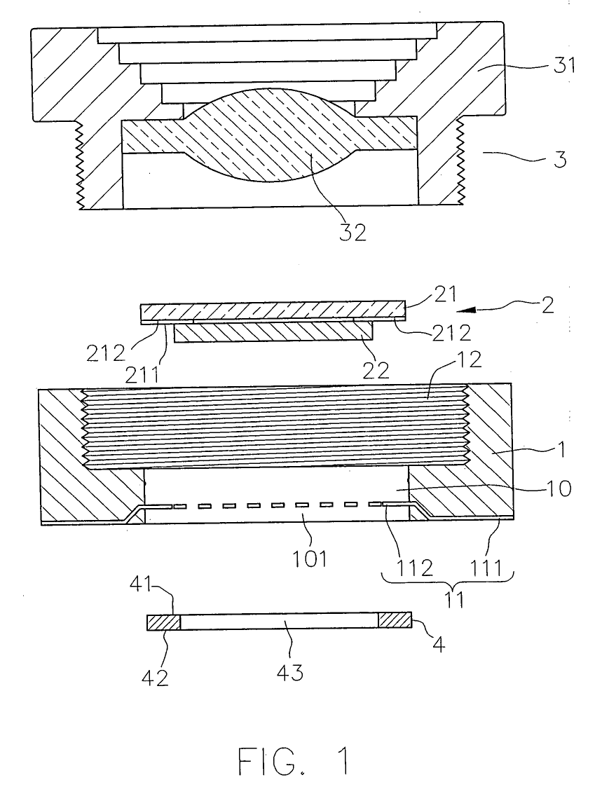

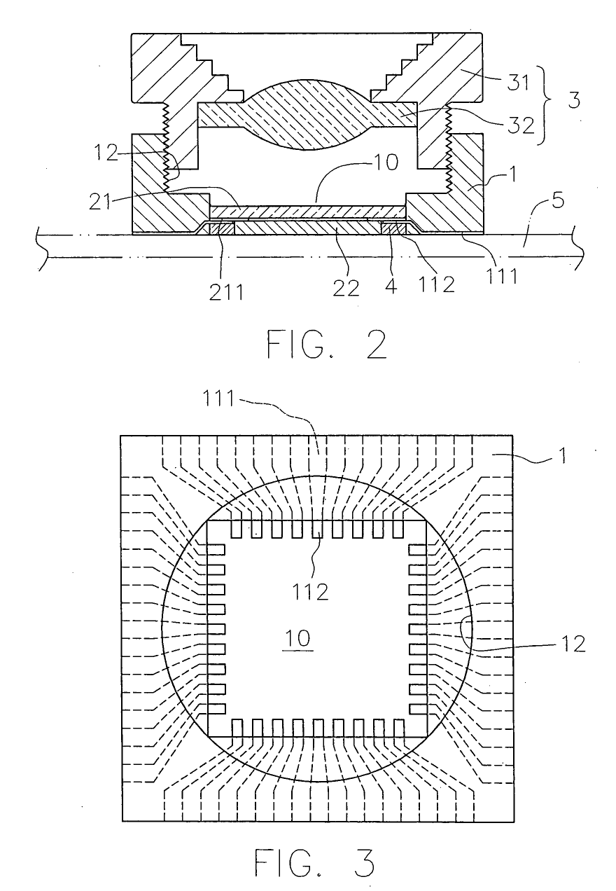

Please refer to FIGS. 1 to 3. The image sensor module of the present invention includes a base seat 1, an image sensor 2 and a lens unit 3 assembled with the base seat 1. The base seat 1 is formed with a cavity 10 serving as an assembly space. The cavity 10 has an opening 101 formed on the bottom face of the base seat 1.

A lead frame 11 is embedded in the base seat 1. The lead frame 11 has multiple outer leads 111 for connecting with a circuit board 5. In addition, the lead frame 11 has multiple inner leads 112 extending from the outer leads 111 into the assembly space.

The image sensor 2 is supported on the inner leads 112. The image sensor 2 is composed of a glass substrate 1 and an image sensing chip 22 bonded with bottom side of the glass substrate 21 by way of flip chip. Multiple circuits 211 are laid on the bottom face of the glass substrate 21 for electrically connecting with the image sensing chip. The circuits 211 extend to four sides 212 of the glass substrate. The four sides 212 of the glass substrate protrude from the image sensing chip, whereby the circuits 211 are exposed to outer side of the image sensing chip for electrically connecting with the inner leads 112.

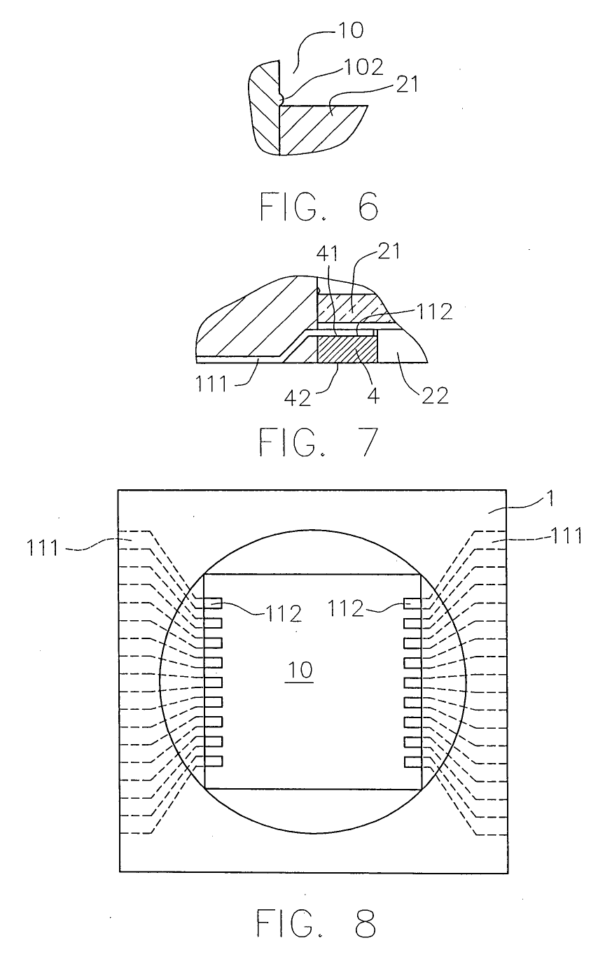

The cavity 10 has a shape corresponding to the shape of the glass substrate 21. The inner wall of the cavity 10 is formed with protruding latch section 102 for clamping the glass substrate between the latch section 102 and the inner leads 112 as shown in FIG. 6.

Referring to FIGS. 1 and 7, a soft pad 4 is disposed at the opening 101 of the cavity. The soft pad 4 has a first surface 41 abutting against the inner leads and an opposite second surface 42 for attaching to the circuit board. The soft pad has a thickness slightly larger than a distance between the bottom face of the base seat and the inner leads. When the base seat is soldered on the circuit board, the soft pad is slightly compressed so as to ensure that the circuits of the glass substrate are well in contact with the inner leads. The soft pad is formed with a perforation 43 in which the image sensing chip is accommodated.

The lens unit 3 is screwed in a thread hole 12 of the base seat above the cavity. The lens unit 3 includes a lens barrel 31 and a lens assembly 32 arranged in the lens barrel 31. By means of turning the lens barrel, the distance between the lens assembly and the image sensor can be adjusted so as to form image on the image sensing chip 22.

After the image sensor is inlaid in the base seat, the lens unit can be screwed on the base seat and precisely aligned with the image sensor.

The lead frame of the base seat serves as an interface for electrically connecting the image sensor with the circuit board. Therefore, various surface adhesion equipments with different precision grades can be applied to the image sensor module without limitation to those sophisticated equipment for adhering the CSP image sensor to the circuit board.

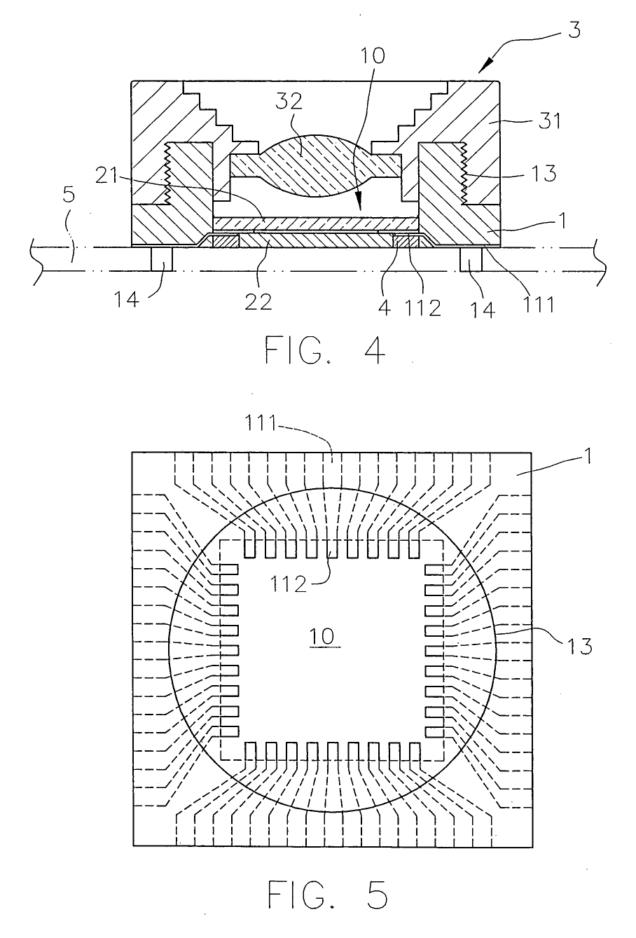

FIG. 4 shows a second embodiment of the present invention, in which the base seat is formed with an outer thread 13 for connecting with the lens unit 3. Several locating tenons 14 project from the bottom of the base seat. The locating tenons 14 can be inserted into the corresponding locating holes of the circuit board to truly locate the base seat on the circuit board 5. FIG. 5 is a top view of the base seat of the second embodiment of the present invention, in which the lead frame is embedded in the base seat.

Due to different design of the image sensor, the circuits of the glass substrate can be alternatively exposed to two lateral sides of the image sensing chip as shown in FIG. 8. Accordingly, the inner leads 112 and outer leads 111 of the lead frame of the base seat 1 are arranged on two sides of the lead frame corresponding to the position of the circuits of the image sensor.

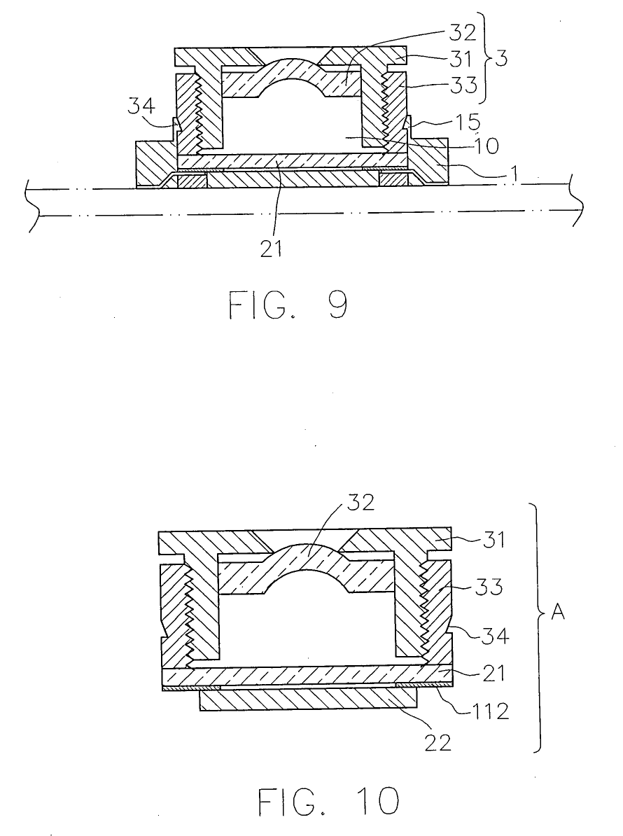

FIG. 9 shows a third embodiment of the image sensor module of the present invention, in which the lens unit 3 includes a lens barrel 31 in which the lens assembly 32 is mounted and a lens holder 33 screwed on the lens barrel 31. The lens holder is connected with the base seat 1. An inner end of the lens holder 33 extends into the cavity 10 of the base seat 1 to abut against the surface of the glass substrate 21 of the image sensor 2. It should be noted that the base seat 1 is formed with engaging hooks 15 and the lens holder 33 is formed with notches 34 in which the engaging hooks 15 are latched so as to locate the lens holder 33 in the cavity 10. The image sensor 2 can be previously adhered to the inner end of the lens holder 33. Accordingly, the lens unit 3 and the image sensor 2 can be assembled to form a module A as shown in FIG. 10. The module A can be tested and adjusted in function. By means of such design, the defects of the assembly of the lens unit and the image sensor can be found earlier. Moreover, the possibility of contamination or damage of the image sensor in succeeding manufacturing procedure can be greatly minified. Therefore, the succeeding user no more needs to deal with the defects of the product derived from the image sensor.

Furthermore, the efficiency of succeeding assembly/installation can be enhanced. The base seat can be previously solely mounted on the circuit board and then assembled with the image sensor and the lens unit without additional test of sensing function. Also, when a succeeding user desires to change the specification of the image sensor and the lens unit, such as pixel value or pickup vision angle, the succeeding user only needs to replace the original module with another type of module composed of an image sensor and a lens unit.

The above embodiments are only used to illustrate the present invention, not intended to limit the scope thereof. Many modifications of the above embodiments can be made without departing from the spirit of the present invention.

What is claimed is:

1. An image pickup module with an image sensor packaged by way of flip chip, comprising:
a base seat formed with an assembly space, the assembly space having an opening formed on a bottom face of the base seat, a lead frame being embedded in the base seat, the lead frame having multiple outer leads for connecting with a circuit board, the lead frame further having multiple inner leads extending from the outer leads into the assembly space;
an image sensor inlaid in the assembly space of the base seat, the image sensor being composed of a glass substrate and an image sensing chip bonded with a surface of the glass substrate by way of flip chip, multiple circuits being laid on the surface of the glass substrate for electrically connecting with the image sensing chip and the inner leads;
a soft pad disposed at the opening of the assembly space, the soft pad having a first surface abutting against the inner leads and an opposite second surface for attaching to the circuit board; and
an image forming unit assembled with the base seat for forming image on the image sensing chip.

2. The image pickup module as claimed in claim 1, wherein the assembly space is a cavity formed on the bottom face of the base seat, the cavity having a shape corresponding to the shape of the glass substrate.

3. The image pickup module as claimed in claim 2, wherein an inner wall of the cavity is formed with protruding latch section for clamping the glass substrate between the latch section and the inner leads.

4. The image pickup module as claimed in claim 3, wherein the image forming unit is a lens unit including a lens barrel and a lens assembly arranged in the lens barrel, the lens barrel being screwed on the base seat above the cavity, whereby by means of turning the lens barrel, the distance between the lens assembly and the image sensor can be adjusted.

5. The image pickup module as claimed in claim 1, wherein the soft pad has a thickness slightly larger than a distance between the bottom face of the base seat and the inner leads, the soft pad being formed with a perforation in which the image sensing chip is accommodated.

6. The image pickup module as claimed in claim 1, wherein several locating tenons project from the bottom of the base seat, whereby the locating tenons can be inserted into corresponding locating holes of the circuit board to truly locate the base seat on the circuit board.

7. The image pickup module as claimed in claim 1, wherein the circuits of the glass substrate extend to two lateral sides of the glass substrate, the lateral sides of the glass substrate protruding from the image sensing chip, whereby the circuits are exposed to outer side of the image sensing chip for electrically connecting with the inner leads.

8. The image pickup module as claimed in claim 1, wherein the circuits of the glass substrate extend to four sides of the glass substrate, the four sides of the glass substrate protruding from the image sensing chip, whereby the circuits are exposed to outer side of the image sensing chip for electrically connecting with the inner leads.

9. The image pickup module as claimed in claim 2, wherein the image forming unit is a lens unit including a lens barrel in which a lens assembly is mounted and a lens holder screwed on the lens barrel, the lens holder being connected with the base seat, an inner end of the lens holder extending into the cavity of the base seat to abut against a surface of the glass substrate of the image sensor.

10. The image pickup module as claimed in claim 9, wherein the base seat is formed with engaging hooks and the lens holder is formed with notches in which the engaging hooks are latched so as to locate the lens holder in the cavity of the base seat.

11. The image pickup module as claimed in claim 10, wherein the soft pad has a thickness slightly larger than a distance between the bottom face of the base seat and the inner leads, the soft pad being formed with a perforation in which the image sensing chip is accommodated.

12. The image pickup module as claimed in claim 9, wherein several locating tenons project from the bottom of the base seat, whereby the locating tenons can be inserted into corresponding locating holes of the circuit board to truly locate the base seat on the circuit board.

13. The image pickup module as claimed in claim 9, wherein the circuits of the glass substrate extend to two lateral sides of the glass substrate, the lateral sides of the glass substrate protruding from the image sensing chip, whereby the circuits are exposed to outer side of the image sensing chip for electrically connecting with the inner leads.

14. The image pickup module as claimed in claim 9, wherein the circuits of the glass substrate extend to four sides of the glass substrate, the four sides of the glass substrate protruding from the image sensing chip, whereby the circuits are exposed to outer side of the image sensing chip for electrically connecting with the inner leads.
